(19) United States
(12) Patent Application Publication
(10) Pub. No.: US 2024/0243082 A1
(43) Pub. Date: Jul. 18, 2024

(54) QUANTUM CHIP, QUANTUM DEVICE, AND QUANTUM COMPUTER

(71) Applicant: NEC Corporation, Tokyo (JP)

(72) Inventors: Tomohiro YAMAJI, Tokyo (JP); Ayuka TADA, Tokyo (JP)

(73) Assignee: NEC Corporation, Tokyo (JP)

(21) Appl. No.: 18/400,164

(22) Filed: Dec. 29, 2023

(30) Foreign Application Priority Data
Jan. 18, 2023 (JP) 2023-006126

(51) Int. Cl. H01L 23/00; H10N 60/80

(52) U.S. Cl. CPC H01L 24/05; H01L 24/04; H01L 24/45; H01L 24/48; H01L 24/49; H10N 60/80; H01L 2224/04042; H01L 2224/05552; H01L 2224/05624; H01L 2224/45124; H01L 2224/45144; H01L 2224/48091; H01L 2224/48225; H01L 2224/49111; H01L 2224/49176

(57) ABSTRACT

Provided is a quantum chip that includes a substrate, a superconducting layer formed on a surface of the substrate, an electrode formed on a surface of the superconducting layer along an outer edge of the substrate, and a periodic structure formed on a surface of the superconducting layer along an outer edge of the substrate.

This application is based upon and claims the benefit of priority from Japanese Patent Application No. 2022-006126, filed on Jan. 18, 2023, the disclosure of which is incorporated herein in its entirety by reference.

### TECHNICAL FIELD

The present disclosure relates to a quantum chip, a quantum device, and a quantum computer.

### BACKGROUND ART

A quantum chip is mounted in a quantum computer in a state of being mounted on a sample holder. The electrode of the quantum chip and the electrode of the sample holder are electrically connected by wire bonding using a wire such as aluminum Al. As the sample holder-side substrate, a printed circuit board (PCB) plated with gold Au to which a wire is easily adhered is used. On the other hand, a superconductor such as niobium Nb to which a wire hardly adheres is formed on the quantum chip. Therefore, the wire is less likely to adhere on the quantum chip side than on the sample holder side. In trial production of a quantum chip, wire bonding is often performed manually. Therefore, when the adhesion of a wire on the quantum chip side fails, it takes time to remove the wire, or the surface of the quantum chip or the PCB is deteriorated.

PTL 1 (JP 2004-228401 A) discloses an oxide semiconductor light-emitting element in which a growth layer including an n-type oxide semiconductor layer, an n-type cladding layer, a light-emitting layer, a p-type cladding layer, and a p-type contact layer is laminated on a substrate. The element of PTL 1 is characterized in that an ohmic electrode made of an oxide of a transition metal containing no nickel Ni, copper Cu, silver Ag, or the like is provided on an n-type oxide semiconductor layer exposed by etching a part of the growth layer. PTL 1 discloses that an Al pad electrode is formed on an ohmic electrode in order to enhance adhesion of a bonding wire.

The wire coupling the signal line/ground acts as an inductor rather than just a conductor. Non-PTL 1 (J. Wenner, et. al., “Wirebond crosstalk and cavity modes in large chip mounts for superconducting qubits,” Supercond. Sci. Technol. 24, (2011) 065001) reports that it is preferable to arrange the wires to the ground as densely and equally as possible in order to reduce the influence of the inductor on the wires.

PTL 2 (JP 2014-056966 A) discloses a method for manufacturing a semiconductor. PTL 2 discloses that a mark serving as a marking for wire bonding is provided relevant to a bonding region of a strip-shaped wire exposed from an opening provided in a solder resist.

In the method of PTL 1, a metal such as Al that easily adheres to a wire is deposited on a superconductor deposited on a quantum chip. In this way, the adhesiveness of the wire on the quantum chip side is improved, and the wire on the quantum chip side is easily adhered. If the adhesiveness of the wire on the quantum chip side is improved, removal of the wire and deterioration of the surface of the quantum chip or the PCB hardly occur.

When a marking serving as a mark for wire bonding is provided on the quantum chip as in the method of PTL 2, workability of wire bonding is improved. However, it is not possible to eliminate the fluctuation of the density of the wires, which is likely to occur in wire bonding performed manually, only by providing a simple marking.

An object of the present disclosure is to provide a quantum chip or the like capable of improving workability of wire bonding and reducing fluctuation in density of bonding wires.

### SUMMARY

A quantum chip according to an aspect of the present disclosure includes a substrate, a superconducting layer formed on a surface of the substrate, an electrode formed on a surface of the superconducting layer along an outer edge of the substrate, and a periodic structure formed on a surface of the superconducting layer along an outer edge of the substrate.

### BRIEF DESCRIPTION OF THE DRAWINGS

Exemplary features and advantages of the present invention will become apparent from the following detailed description when taken with the accompanying drawings in which:

FIG. 1 is a conceptual diagram illustrating an example of a configuration of a quantum chip according to the present disclosure;

FIG. 2 is a conceptual diagram illustrating an example of a positional relationship between a part of an electrode of a quantum chip and a sample holder-side substrate according to the present disclosure;

FIG. 3 is a conceptual diagram illustrating an example of a state in which a electrode of a quantum chip and an electrode of a sample holder-side substrate according to the present disclosure are connected by a bonding wire;

FIG. 4 is a conceptual diagram illustrating an example of a state in which the quantum chip according to the present disclosure is mounted on a sample holder;

FIG. 5 is a conceptual diagram illustrating an example of a configuration of a quantum chip according to the present disclosure;

FIG. 6 is a conceptual diagram illustrating an example of a positional relationship between a part of an electrode of a quantum chip and a sample holder-side substrate according to the present disclosure;

FIG. 7 is a conceptual diagram illustrating an example of a state in which an electrode of a quantum chip according to the present disclosure and an electrode of a sample holder-side substrate are connected by a bonding wire;

FIG. 8 is a conceptual diagram illustrating an example of a configuration of a quantum device according to the present disclosure;

FIG. 9 is a conceptual diagram illustrating an example of a positional relationship between a part of an electrode of a quantum chip constituting a quantum device according to the present disclosure and a sample holder-side substrate;

FIG. 10 is a conceptual diagram illustrating an example of a state in which an electrode of a quantum chip constituting a quantum device according to the present disclosure and an electrode of a sample holder-side substrate are connected by a bonding wire;

FIG. 11 is a conceptual diagram illustrating an example of a state in which an electrode of a quantum chip constituting a quantum device according to a modification of the present disclosure and an electrode of a sample holder-side substrate are connected by a bonding wire;

FIG. 12 is a block diagram illustrating an example of a configuration of a quantum computer according to the present disclosure; and

FIG. 13 is a conceptual diagram illustrating an example of a configuration of a quantum chip according to the present disclosure.

### EXAMPLE EMBODIMENT

Example embodiments of the present invention will be described below with reference to the drawings. In the following example embodiments, technically preferable limitations are imposed to carry out the present invention, but the scope of this invention is not limited to the following description. In all drawings used to describe the following example embodiments, the same reference numerals denote similar parts unless otherwise specified. In addition, in the following example embodiments, a repetitive description of similar configurations or arrangements and operations may be omitted.

### First Example Embodiment

First, a quantum chip according to a first example embodiment will be described with reference to the drawings. The quantum chip of the present example embodiment is mounted on a sample holder. The quantum chip of the present example embodiment is electrically connected to a sample holder-side substrate using a bonding wire. The quantum chip of the present example embodiment is mounted on a quantum computer in a state of being mounted on the sample holder. The quantum chip of the present example embodiment is mounted inside a dilution refrigerator that achieves a cryogenic environment of equal to or less than 10 milliKelvin (mK) in a state of being mounted on the sample holder.

### (Configuration)

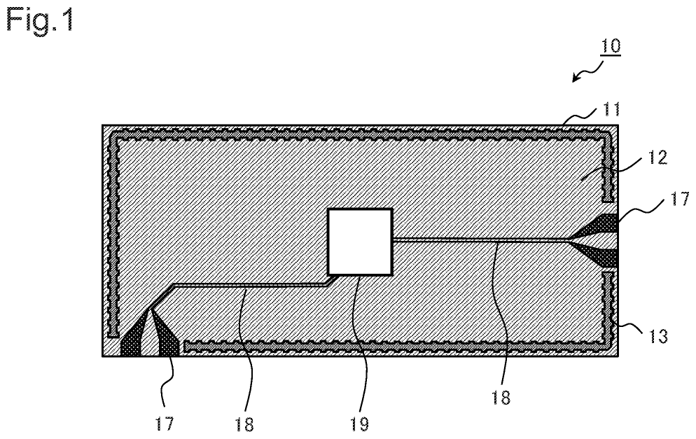

FIG. 1 is a conceptual diagram illustrating an example of a configuration of a quantum chip 10 according to the present example embodiment. The quantum chip 10 includes a substrate 11, a superconducting layer 12, an electrode 13, a terminal 17, a signal line 18, and a quantum circuit 19. In the present example embodiment, an example in which the quantum chip 10 is a microwave circuit will be described. For example, the quantum chip 10 may be a linear resonator, a capacity, or the like. The quantum chip 10 may be achieved not by a planar circuit but by a circuit three-dimensionally formed such as a three-dimensional circuit or a three-dimensional quantum circuit.

The superconducting layer 12 is formed on a surface of the substrate 11. For example, a material of the substrate 11 is high-resistance silicon, sapphire, diamond, or the like. The material of the substrate 11 is not limited to high-resistance silicon, sapphire, and diamond. For example, the material of the substrate 11 may be a compound semiconductor such as a group III-V semiconductor or a group II-VI semiconductor. The substrate 11 may be a single crystal, a polycrystal, or an amorphous material.

The superconducting layer 12 is formed on the surface of the substrate 11. The superconducting layer 12 is a layer of a material exhibiting superconductivity at a use temperature of the quantum chip 10. The material of the superconducting layer 12 is not particularly limited as long as it exhibits superconductivity at the use temperature of the quantum chip 10. For example, the material of the superconducting layer 12 is a metal such as niobium Nb, tantalum Ta, aluminum Al, indium In, lead Pb, tin Sn, rhenium Re, palladium Pd, titanium Ti, or molybdenum Mo. For example, the material of the superconducting layer 12 may be an alloy containing at least one of these metals. For example, the material of the superconducting layer 12 may be a nitride such as a titanium nitride, a niobium nitride, or a tantalum nitride. For example, the superconducting layer 12 is formed by a film forming method such as sputtering or atomic layer deposition (ALD).

The electrode 13 is formed on the surface of the superconducting layer 12 along the outer edge of the substrate 11. The electrode 13 is made of a material having high adhesiveness to a bonding wire. For example, the electrode 13 is a metal such as aluminum Al. A method for forming the electrode 13 is not particularly limited. For example, the electrode 13 is formed by reactive ion etching (RIE). The electrode 13 may be a terminal connected to the signal line 18 or may be ground.

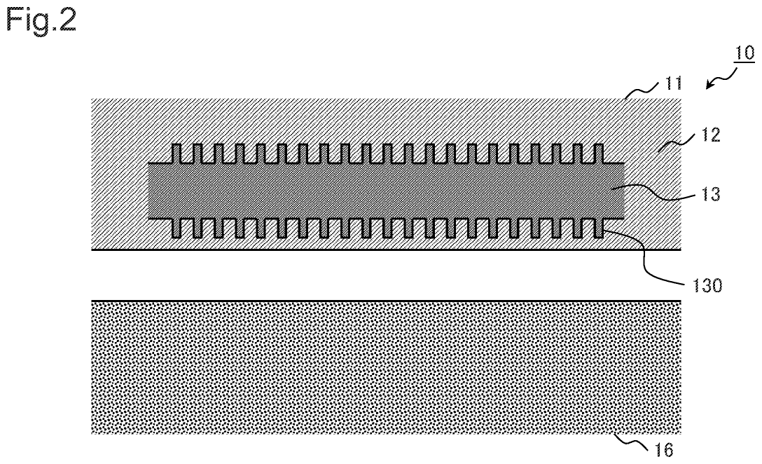

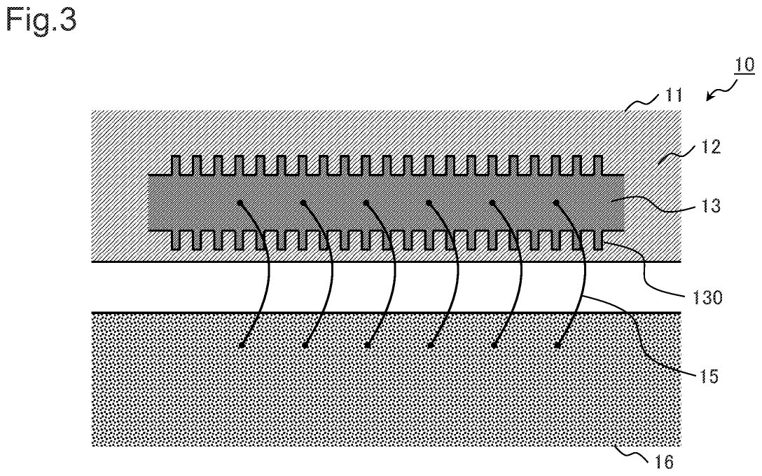

FIG. 2 is a conceptual diagram in which a part of the electrode 13 of the quantum chip 10 is enlarged. FIG. 2 illustrates a part (electrode) of a sample holder-side substrate 16. FIG. 3 is a conceptual diagram illustrating a state in which the electrode 13 of the quantum chip 10 and the electrode of the sample holder-side substrate 16 are electrically connected by a bonding wire 15. For example, an electrode of the sample holder-side substrate 16 is plated with Au gold to which the bonding wire 15 easily adheres. For example, the sample holder-side substrate 16 is achieved by a printed circuit board (PCB) or the like plated with Au gold to which the bonding wire 15 easily adheres. For example, the electrode 13 of the quantum chip 10 and the electrode of the sample holder-side substrate 16 are bonded to the bonding wire 15 using ultrasonic waves.

The electrode 13 has a periodic structure 130. The periodic structure 130 includes a plurality of protrusions protruding in a direction perpendicular to the longitudinal direction of the electrode 13. That is, the periodic structure 130 has a shape having periodicity in a direction perpendicular to the outer edge of the substrate 11. The periodic structure 130 is formed as a marking of a bonding position of the bonding wire 15 used for connection with the electrode of the sample holder-side substrate 16. When work is performed using the periodicity of the periodic structure 130 as a marking, workability of wire bonding is improved, and fluctuations in the density of the bonding wires 15 are reduced. For example, the plurality of protrusions constituting the periodic structure 130 has periodicity of a fraction over an integer with respect to the interval between the adjacent bonding wires 15 (the integer is 2 or more). If the interval between the protrusions constituting the periodic structure 130 is set to ½ to 1/10 of the interval between the bonding wires 15, when bonding fails, wire bonding can be redone by shifting the bonding position. For example, when there is a portion where it is difficult for the bonding wire 15 to adhere on at least one side of the sample holder-side substrate 16 and the quantum chip 10, the bonding position can be shifted with reference to the periodic structure 130. Without the marking such as the periodic structure 130, when the wire bonding fails, there is a possibility that the wire bonding is tried again at a place where the bonding wire 15 is difficult to adhere, and the failure is repeated many times.

When the bonding position is shifted using the periodicity of the periodic structure 130 as a marking, for example, the bonding position may be shifted using a position of a protrusion adjacent to a protrusion used as a marking when the bonding fails as a marking. In the subsequent wire bonding, the bonding positions may be sequentially shifted using the position of the protrusion adjacent to the protrusion, which is a marking of the normal bonding scheduled position, as a marking. In this way, after the bonding position where the bonding has failed, the interval between the bonding wires 15 is maintained at a normal interval. In this way, a set of bonding wires 15 having different intervals is formed to avoid a portion that is difficult to adhere, and the other sets of adjacent bonding wires 15 are kept at equal intervals. When the interval between the protrusions is within the above range (½ to 1/10), the difference in the interval between the bonded portions shifted from the normal interval of the bonding wire 15 can be reduced. By setting the interval between the protrusions to ⅓ to 1/10 of the interval between the bonding wires 15, or further setting the interval to ¼ to 1/10 of the interval between the bonding wires 15, it is possible to further reduce the difference in the interval between the bonding portions shifted from the normal interval of the bonding wire 15. If the interval between the protrusions is too narrow with respect to the normal interval of the bonding wire 15, the number of protrusions between the adjacent bonding wires 15 increases, and it becomes difficult to use the protrusion as a guide of the bonding position. Therefore, it is preferable that the interval between the adjacent bonding wires 15 is set within the above range.

FIGS. 2 and 3 illustrate an example in which the periodic structure 130 includes a plurality of rectangular protrusions. For example, the lengths of the protrusions constituting the periodic structure 130 may be different between the inward direction of the substrate 11 and the outward direction of the substrate 11. The protrusions may be formed to be conspicuous by extending the lengths of the protrusions disposed inside the substrate 11. For example, the periodic structure 130 may be formed only in the inward direction of the substrate 11. In this case, since the longitudinal direction of the electrode 13 can be formed along the outer edge of the substrate 11, the length of the bonding wire 15 can be shortened. If the length of the bonding wire 15 can be shortened, the inductance of the bonding wire 15 can be reduced.

The length of the protrusion constituting the periodic structure 130 may be different from the length of the adjacent protrusion. For example, like a scale of a ruler, the periodic structure 130 may have a shape in which long protrusions and short protrusions are periodically arranged. In the case of such a shape, the long protrusion may be formed to stand out by increasing the width of the long protrusion. The shape of the protrusion may be not a rectangle but a triangle such as a right triangle or an isosceles triangle. The tip of the protrusion may be rounded in an arc shape. The protrusions constituting the periodic structure 130 may protrude in a direction not perpendicular to the longitudinal direction of the electrode 13. The periodic structure 130 may have a shape having periodicity such as a sine wave extending along the longitudinal direction of the electrode 13.

The periodic structure 130 of the electrode 13 of the present example embodiment is suitable for a superconducting circuit in which uniformity of the density of the bonding wires 15 is required. The bonding wire 15 includes a wire that connects the ground of the quantum chip 10 and the sample holder-side substrate 16, and a wire that connects the terminal 17 of the quantum chip 10 and the signal line of the sample holder-side substrate 16. It is preferable that the bonding wire 15 connecting the ground is dense and uniform. Since a large number of bonding wires 15 connecting the signal lines cannot strike a narrow electrode of the terminal 17, uniformity is not required as compared with the bonding wire 15 connecting the ground.

For example, the superconducting layer 12 may be removed by etching, and a periodic mark serving as a marking for wire bonding may be provided on the superconducting layer 12. A wiring pattern serving as a marking for wire bonding may be provided on the upper surface of the superconducting layer 12 along the electrode 13. These markings may be provided relevant to the periodic structure 130 or may be provided instead of the periodic structure 130.

The bonding wire 15 is a wire that connects the electrode 13 of the quantum chip 10 and the electrode of the sample holder-side substrate 16. When the electrode 13 is the ground, in order to connect the quantum chip 10 and the ground of the sample holder-side substrate 16 to each other, it is preferable to perform bonding uniformly with the bonding wire 15 having as high density as possible.

As a material of the bonding wire 15, a material that easily adheres to the electrode 13 is selected. For example, when the material of the electrode 13 is aluminum Al, aluminum Al is selected as the material of the bonding wire 15. Aluminum Al is in a superconducting state at a use temperature of the quantum chip 10. Since aluminum Al is relatively flexible, it is easy to perform bonding. For example, metal such as gold Au may be selected as the material of the bonding wire 15.

The terminal 17 is a terminal connected to the signal line 18. For example, the terminal 17 is made of the same material as the electrode 13. The terminal 17 is connected to the electrode of the sample holder-side substrate 16 by the bonding wire 15. A signal supplied from an external signal source (not illustrated) is input to the terminal 17 via the sample holder-side substrate 16. A signal from the quantum circuit 19 propagates to the terminal 17 via the signal line 18. For example, the signal propagated from the quantum circuit 19 to the terminal 17 via the signal line 18 is transmitted to an external readout circuit (not illustrated) via the sample holder-side substrate 16. For example, a test signal used for characteristic evaluation, operation confirmation, and the like is input to the terminal 17. For example, a signal subjected to arithmetic processing in the quantum circuit 19 is input to the terminal 17. The signal input/output via the terminal 17 is not particularly limited.

The signal line 18 connects the terminal 17 and the quantum circuit 19. For example, the signal line 18 is a waveguide such as a coplanar waveguide. The signal from the terminal 17 propagates to the signal line 18. The signal propagated through the signal line 18 from the terminal 17 is input to the quantum circuit 19. A signal from the quantum circuit 19 propagates to the signal line 18. The signal propagated from the quantum circuit 19 to the signal line 18 travels toward the terminal 17. For example, in the superconductor formed on the surface of the substrate 11, the signal line 18 can be formed by removing the superconductor between the ground plane and the conductor forming the signal line 18 and exposing and patterning the substrate 11. For example, the material of the signal line 18 is niobium Nb or aluminum Al in a superconducting state at the use temperature of the quantum chip 10. However, the material of the signal line 18 is not limited to niobium Nb or aluminum Al as long as it is in a superconducting state at the use temperature of the quantum chip 10.

The quantum circuit 19 is connected to the signal line 18. For example, the quantum circuit 19 includes at least one quantum bit including a Josephson parametric oscillator JPO and at least one coupler. The at least one quantum bit is connected to the at least one coupler. For example, the quantum circuit 19 has a configuration in which a plurality of quantum bits and a plurality of coupling circuits are combined. The quantum circuit 19 may be a circuit including at least one Josephson parametric oscillator JPO. The quantum circuit 19 may be a circuit including at least one coupler. The wiring pattern of the quantum circuit 19 is not particularly limited. The signal propagated through the signal line 18 is input to the quantum circuit 19. The quantum circuit 19 performs a quantum computation on the input signal. The quantum computation executed by the quantum circuit 19 is not particularly limited as long as it is an operation using a quantum bit. The quantum circuit 19 outputs the quantized signal to the signal line 18. The material of the quantum circuit 19 is mainly made of a superconducting material. In the example of FIG. 1, the outer shape of the quantum circuit 19 is a square, but the outer shape of the quantum circuit 19 is not particularly limited. For example, the quantum circuit 19 can be formed by patterning a superconducting material formed on the surface of the substrate 11.

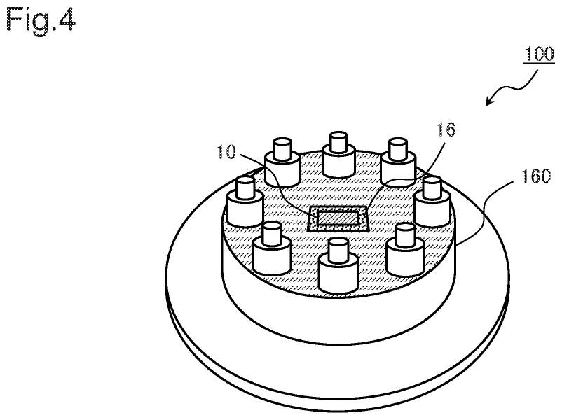

FIG. 4 is a conceptual diagram illustrating an example of a state in which the quantum chip 10 is mounted on a sample holder 160. A device in which a quantum chip is mounted on the sample holder 160 is referred to as a quantum device 100. The quantum chip 10 is mounted inside a dilution refrigerator of a quantum computer (not illustrated) in a state of being mounted on the sample holder 160. The quantum chip 10 is used in a cryogenic environment of equal to or less than 10 milliKelvin (mK) inside the dilution refrigerator.

As described above, the quantum chip of the present example embodiment includes the substrate, the superconducting layer, the electrode, and the periodic structure. The substrate is a high-resistance semiconductor substrate having higher electric resistance than a general semiconductor. The superconducting layer is formed on the surface of the substrate. The electrode is formed on the surface of the superconducting layer along the outer edge of the substrate. The periodic structure is formed on the surface of the superconducting layer along the outer edge of the substrate as a marking for a plurality of bonding wires connected to the electrode. The periodic structure includes a plurality of protrusions formed on the electrode. The plurality of protrusions protrudes in a direction perpendicular to the outer edge of the substrate.

In trial production of a quantum chip, wire bonding is often performed manually using a wire bonder while visually recognizing an adhesion site with a microscope. In a general quantum chip, the PCB/quantum chip has no scale as a reference. Therefore, even a skilled operator varies in the number and density of bonding wires. When the bonding of the bonding wire fails, it is necessary to remove the bonding wire using tweezers or the like. Therefore, when the bonding of the bonding wire fails, it takes time to remove the wire, or the surface of the quantum chip or the PCB is deteriorated.

The bonding wires that couple the signal lines/ground act as inductors rather than just conductors. In order to reduce the influence of the inductor of the wire, it is preferable that the wires are arranged in the ground as closely as possible and at equal intervals. In order to reduce the influence of the inductor of the wire, it is preferable that the wires are arranged on the ground as short as possible.

The quantum chip of the present example embodiment has a periodic structure formed on the surface of the superconducting layer along the outer edge of the substrate. The periodic structure includes a plurality of protrusions formed on the electrode. The periodic structure serves as a marking for wire bonding performed on the electrode. Therefore, according to the present example embodiment, by working with the periodicity of the periodic structure as a marking, workability of wire bonding is improved, and fluctuations in the density of the bonding wires can be reduced. The configuration of the present example embodiment can be applied not only to a quantum chip but also to a general semiconductor chip.

The periodicity of the periodic structure serves as a reference for automatic wire bonding as well as manual wire bonding. Compared with a normal wire bonder, a wire bonder configured to automatically perform wire bonding in accordance with periodicity of a periodic structure can reduce fluctuation in density of the bonding wires.

In an aspect of the present example embodiment, the periodic structure has periodicity of a fraction over an integer with respect to an interval of the plurality of bonding wires connected to the electrode. For example, the periodic structure has periodicity of ½ to 1/10 relative to the interval of adjacent bonding wires. Without the marking such as the periodic structure, when the wire bonding fails, there is a possibility that the wire bonding is tried again at a place where the bonding wire is difficult to adhere, and the failure is repeated many times. According to the present aspect, when there is a portion where it is difficult for the bonding wire to adhere on at least one side of the sample holder-side substrate and the quantum chip, the bonding position can be shifted with reference to the periodic structure. Therefore, according to the present aspect, when the wire bonding fails, the wire bonding can be performed again while being shifted to the position of any marking included in the periodic structure between the adjacent bonding wires.

In one aspect of the present example embodiment, the periodic structure has a shape having periodicity in a direction perpendicular to the outer edge of the substrate. For example, the periodic structure includes a plurality of protrusions. For example, the periodic structure is a periodic shape such as a sine wave. According to the present aspect, by working with the periodicity of the periodic structure as a marking, workability of wire bonding is improved, and fluctuations in the density of the bonding wires can be reduced.

### Second Example Embodiment

Next, a quantum chip according to a second example embodiment will be described with reference to the drawings. The quantum chip of the present example embodiment is different from that of the first example embodiment in the periodic structure of the electrode. The periodic structure of the electrode formed in the quantum chip of the present example embodiment may be combined with the periodic structure of the electrode formed in the quantum chip of the first example embodiment.

### (Configuration)

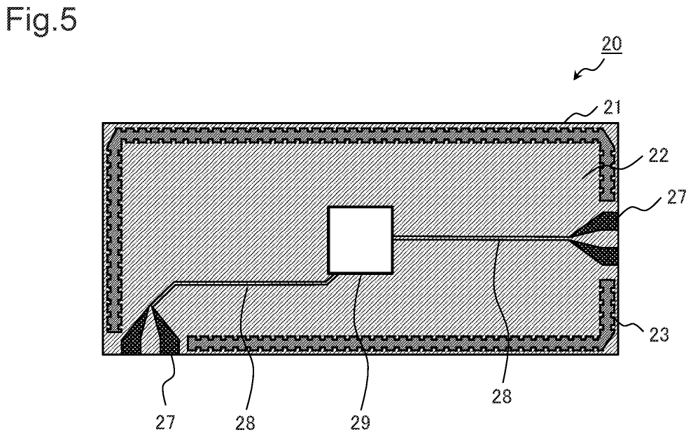

FIG. 5 is a conceptual diagram illustrating an example of a configuration of a quantum chip 20 according to the present example embodiment. The quantum chip 20 includes a substrate 21, a superconducting layer 22, an electrode 23, a terminal 27, a signal line 28, and a quantum circuit 29.

The substrate 21 has the same configuration as the substrate 11 of the first example embodiment. The substrate 21 is a high-resistance semiconductor substrate having higher electric resistance than a general semiconductor.

The superconducting layer 22 has the same configuration as the superconducting layer 12 of the first example embodiment. The superconducting layer 22 is formed on the surface of the substrate 21. The superconducting layer 22 is a layer of a material exhibiting superconductivity at a use temperature of the quantum chip 20.

The electrode 23 is formed on the surface of the superconducting layer 22 along the outer edge of the substrate 21. The electrode 23 is made of a material having high adhesiveness to a bonding wire. The electrode 23 is made of the same material as the electrode 13 of the first example embodiment. For example, the electrode 23 is a metal such as aluminum Al. A method for forming the electrode 23 is not particularly limited. For example, the electrode 23 is formed by etching. The electrode 23 may be a terminal connected to the signal line 28 or may be ground.

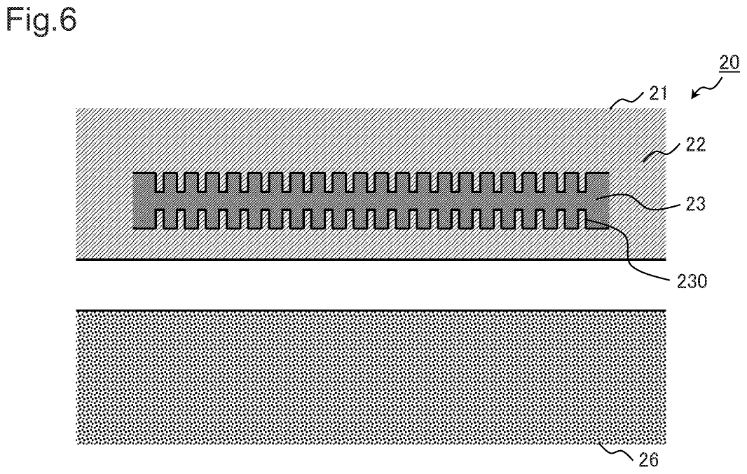

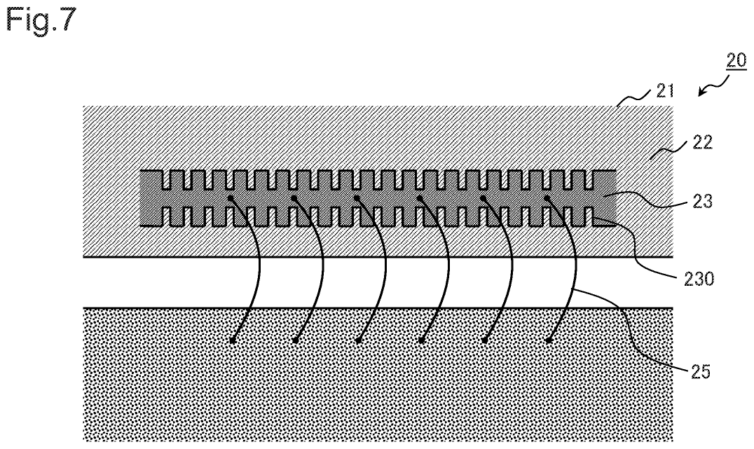

FIG. 6 is a conceptual diagram in which a part of the electrode 23 of the quantum chip 20 is enlarged. FIG. 6 illustrates a part (electrode) of a sample holder-side substrate 26. FIG. 7 is a conceptual diagram illustrating a state in which the electrode 23 of the quantum chip 20 and the electrode of the sample holder-side substrate 26 are electrically connected by a bonding wire 25. For example, an electrode of the sample holder-side substrate 26 is plated with Au gold to which the bonding wire 25 easily adheres. For example, the electrode 23 of the quantum chip 20 and the electrode of the sample holder-side substrate 26 are bonded to the bonding wire 25 using ultrasonic waves.

The electrode 23 has a periodic structure 230. The periodic structure 230 includes a plurality of recesses recessed in a direction perpendicular to the longitudinal direction of the electrode 23. That is, the periodic structure 230 has a shape having periodicity in a direction perpendicular to the outer edge of the substrate 21. The periodic structure 230 is formed as a marking of a bonding position of the bonding wire 25 used for connection with the electrode of the sample holder-side substrate 26. When work is performed using the periodicity of the periodic structure 230 as a marking, workability of wire bonding is improved, and fluctuations in the density of the bonding wires 25 are reduced. For example, the plurality of recesses constituting the periodic structure 230 has periodicity of a fraction over an integer with respect to the interval between the adjacent bonding wires 25 (the integer is 2 or more). If the interval between the plurality of recesses constituting the periodic structure 230 is set to ½ to 1/10 of the interval between the bonding wires 25, when bonding fails, wire bonding can be redone by shifting the bonding position. For example, when there is a portion where it is difficult for the bonding wire 25 to adhere on at least one side of the sample holder-side substrate 26 and the quantum chip 20, the bonding position can be shifted with reference to the periodic structure 230. Without the marking such as the periodic structure 230, when the wire bonding fails, there is a possibility that the wire bonding is tried again at a place where the bonding wire 25 is difficult to adhere, and the failure is repeated many times.

FIGS. 6 and 7 illustrate examples in which the periodic structure 230 includes a plurality of rectangular recesses. For example, the depth of the recess constituting the periodic structure 230 may be different between the inward direction of the substrate 21 and the outward direction of the substrate 21. The recess formed inside the substrate 21 may be deepened so that the recess is conspicuous. For example, the periodic structure 230 may be formed only in the inward direction of the substrate 21. In this case, since there is no periodic structure 230 on the outer edge side of the substrate 21, the degree of freedom in selecting the bonding portion of the bonding wire 25 is improved.

The depth of the recess constituting the periodic structure 230 may be different from the depth of the adjacent recess. For example, like a scale of a ruler, the periodic structure 230 may have a shape in which a deep protrusion and a shallow protrusion are periodically arranged. In the case of such a shape, the deep protrusion may be formed to stand out by increasing the width of the deep recess. The shape of the recess may be not a rectangle but a triangle such as a right triangle or an isosceles triangle. The bottom of the recess may be rounded in an arc shape. The recess constituting the periodic structure 230 may be recessed in a direction not perpendicular to the longitudinal direction of the electrode 23. The periodic structure 230 may have a shape having periodicity such as a sine wave extending along the longitudinal direction of the electrode 23.

The periodic structure 230 of the electrode 23 of the present example embodiment is suitable for a superconducting circuit in which uniformity of the density of the bonding wires 25 is required. The bonding wire 25 includes a wire that connects the grounds of the quantum chip 20 and the sample holder-side substrate 26 to each other, and a wire that connects signal lines of the quantum chip 20 and the sample holder-side substrate 26 to each other. It is preferable that the bonding wire 25 connecting the ground is dense and uniform. The bonding wires 25 connecting the signal lines cannot strike many narrow electrodes, and thus uniformity is not required as compared with the bonding wires 25 connecting the ground.

For example, the superconducting layer 22 may be removed by lithography, and a periodic defect serving as a marking of wire bonding may be provided in the superconducting layer 22. A wiring pattern serving as a marking for wire bonding may be provided on the upper surface of the superconducting layer 22 along the electrode 23. These markings may be provided relevant to the periodic structure 230 or may be provided instead of the periodic structure 230.

The bonding wire 25 has the same configuration as the bonding wire 15 of the first example embodiment. The bonding wire 25 is a wire that connects the electrode 23 of the quantum chip 20 and the electrode of the sample holder-side substrate 26. When the electrode 23 is the ground, in order to connect the quantum chip 20 and the ground of the sample holder-side substrate 26 to each other, it is preferable to perform bonding uniformly with the bonding wire 25 having as high density as possible.

The terminal 27 has the same configuration as the terminal 17 of the first example embodiment. The terminal 27 is a terminal connected to the signal line 28. The terminal 27 is connected to the electrode of the sample holder-side substrate 26 by the bonding wire 25. A signal supplied from an external signal source (not illustrated) is input to the terminal 27 via the sample holder-side substrate 26. A signal from the quantum circuit 29 propagates to the terminal 27 via the signal line 28. For example, the signal propagated from the quantum circuit 29 to the terminal 27 via the signal line 28 is transmitted to an external readout circuit (not illustrated) via the sample holder-side substrate 26. For example, a test signal used for characteristic evaluation, operation confirmation, and the like is input to the terminal 27. For example, a signal subjected to arithmetic processing in the quantum circuit 29 is input to the terminal 27. The signal input/output via the terminal 27 is not particularly limited.

The signal line 28 has the same configuration as the signal line 18 of the first example embodiment. The signal line 28 connects the terminal 27 and the quantum circuit 29. The signal from the terminal 27 propagates to the signal line 28. The signal propagated through the signal line 28 from the terminal 27 is input to the quantum circuit 29. A signal from the quantum circuit 29 propagates to the signal line 28. The signal propagated from the quantum circuit 29 to the signal line 28 travels toward the terminal 27.

The quantum circuit 29 has the same configuration as the quantum circuit 19 of the first example embodiment. The quantum circuit 29 is connected to the signal line 28. For example, the quantum circuit 29 includes at least one quantum bit including the Josephson parametric oscillator JPO and at least one coupler. The at least one quantum bit is connected to the at least one coupler. The quantum circuit 29 may be a circuit including at least one Josephson parametric oscillator JPO. The quantum circuit 29 may be a circuit including at least one coupler. The signal propagated through the signal line 28 is input to the quantum circuit 29. The quantum circuit 29 performs a quantum computation on the input signal. The quantum circuit 29 outputs the quantized signal to the signal line 28.

As described above, the quantum chip of the present example embodiment includes the substrate, the superconducting layer, the electrode, and the periodic structure. The substrate is a high-resistance semiconductor substrate having higher electric resistance than a general semiconductor. The superconducting layer is formed on the surface of the substrate. The electrode is formed on the surface of the superconducting layer along the outer edge of the substrate. The periodic structure is formed on the surface of the superconducting layer along the outer edge of the substrate as a marking for a plurality of bonding wires connected to the electrode. The periodic structure includes a plurality of recesses formed on the electrode. The plurality of recesses is recessed in a direction perpendicular to the outer edge of the substrate.

The quantum chip of the present example embodiment has a periodic structure formed on the surface of the superconducting layer along the outer edge of the substrate. The periodic structure includes a plurality of recesses formed on the electrode. The periodic structure serves as a marking for wire bonding performed on the electrode. Therefore, according to the present example embodiment, by working with the periodicity of the periodic structure as a marking, workability of wire bonding is improved, and fluctuations in the density of the bonding wires can be reduced.

In an aspect of the present example embodiment, the periodic structure has periodicity of a fraction over an integer with respect to an interval of the plurality of bonding wires connected to the electrode. For example, the periodic structure has periodicity of ½ to 1/10 relative to the interval of adjacent bonding wires. According to the present aspect, when the wire bonding fails, the wire bonding can be performed again while being shifted to the position of any marking included in the periodic structure between the adjacent bonding wires.

In one aspect of the present example embodiment, the periodic structure has a shape having periodicity in a direction perpendicular to the outer edge of the substrate. For example, the periodic structure includes a plurality of recesses. For example, the periodic structure is a periodic shape such as a sine wave. According to the present aspect, by working with the periodicity of the periodic structure as a marking, workability of wire bonding is improved, and fluctuations in the density of the bonding wires can be reduced.

### Third Example Embodiment

Next, a quantum device according to a third example embodiment will be described with reference to the drawings. The quantum device of the present example embodiment includes the quantum chips of the first and second example embodiments. The quantum device of the present example embodiment is different from the first and second example embodiments in that a marking of a bonding position of a bonding wire is also formed on the sample holder side.

### (Configuration)

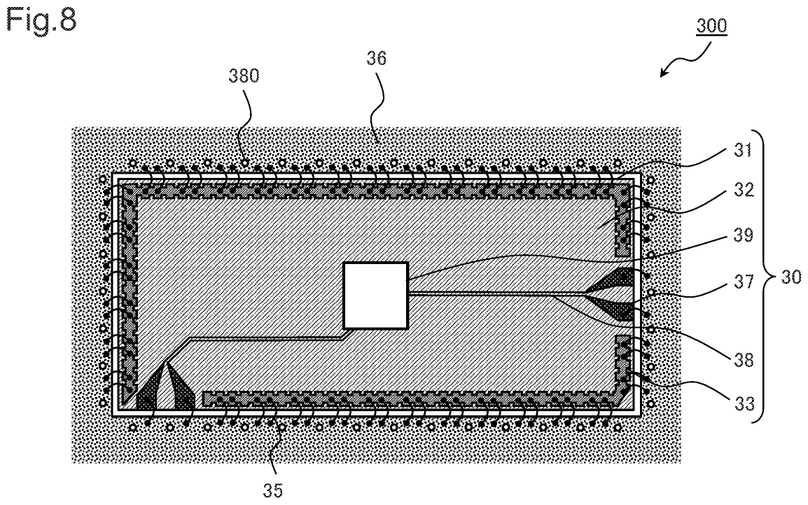

FIG. 8 is a conceptual diagram illustrating an example of a configuration of a quantum device 300 according to the present example embodiment. The quantum device 300 includes a quantum chip 30 and a sample holder. The quantum chip 30 and a sample holder-side substrate 36 are electrically connected via a bonding wire 35.

The quantum chip 30 includes a substrate 31, a superconducting layer 32, an electrode 33, a terminal 37, a signal line 38, and a quantum circuit 39. Similarly to the periodic structure 230 of the second example embodiment, a periodic structure 330 is formed in the electrode 33. The quantum chip 30 is mounted on the sample holder-side substrate 36 via the bonding wire 35. In the present example embodiment, the quantum chip 30 has the same configuration as the quantum chip 20 of the second example embodiment. The quantum chip 30 may be the quantum chip 10 of the first example embodiment. Hereinafter, the description of the quantum chip 30 is omitted.

An opening in which the quantum chip 30 is mounted is formed in the sample holder-side substrate 36. A pattern 380 is formed on the surface of the sample holder-side substrate 36. The pattern 380 includes a plurality of through holes formed along the inner side of the opening portion of the sample holder-side substrate 36. The plurality of through holes penetrates the sample holder-side substrate 36. The pattern 380 may be a hole formed on the surface of the sample holder-side substrate instead of the through hole. The pattern 380 may have a periodic shape or pattern formed on the surface of the sample holder-side substrate 36.

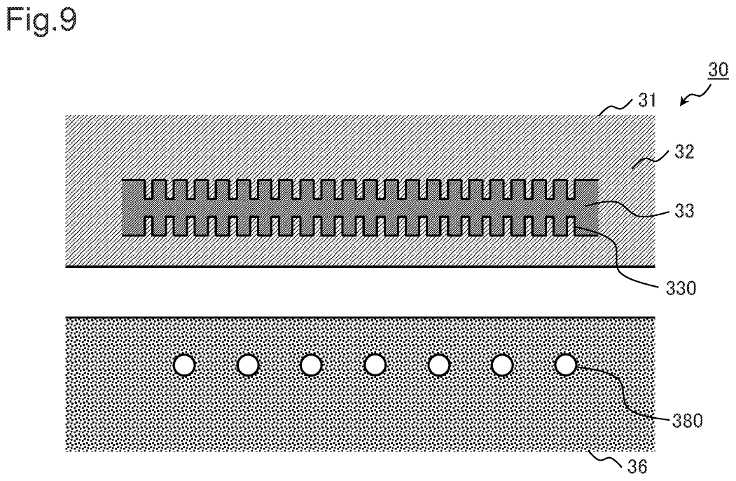

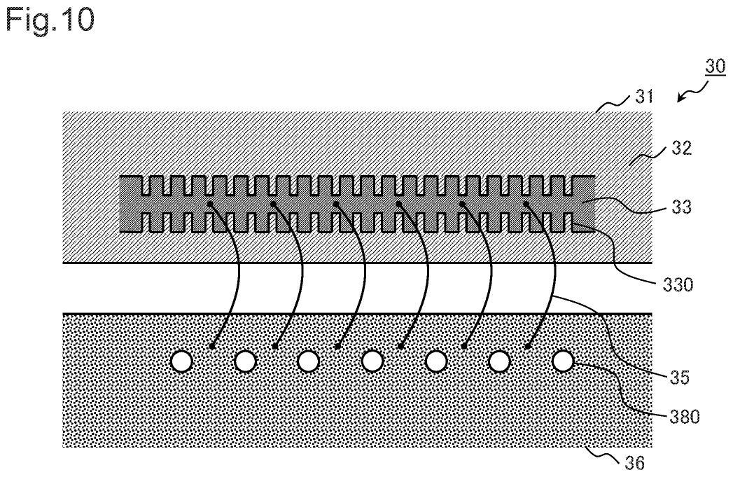

FIG. 9 is a conceptual diagram in which a part of the electrode 33 of the quantum chip 30 is enlarged. FIG. 9 illustrates a part (electrode) of the sample holder-side substrate 36. FIG. 10 is a conceptual diagram illustrating a state in which the electrode 33 of the quantum chip 30 and the electrode of the sample holder-side substrate 36 are electrically connected by a bonding wire 35. For example, an electrode of the sample holder-side substrate 36 is plated with Au gold to which the bonding wire 35 easily adheres. For example, the electrode 33 of the quantum chip 30 and the electrode of the sample holder-side substrate 36 are bonded to the bonding wire 35 using ultrasonic waves.

FIGS. 9 and 10 illustrate an example in which the pattern 380 includes a plurality of through holes. The through holes constituting the pattern 380 are formed in accordance with the periodicity of the periodic structure 330 of the quantum chip 30. The diameters of the through holes constituting the pattern 380 may be different from the diameters of the adjacent through holes. For example, the pattern 380 may have a shape in which a through hole having a large diameter and a through hole having a small diameter are periodically arranged. The shape of the through hole may be not a circle but a rectangle or a triangle. The pattern 380 may have a shape having periodicity such as a sine wave extending along the longitudinal direction of the electrode 33 of the quantum chip 30.

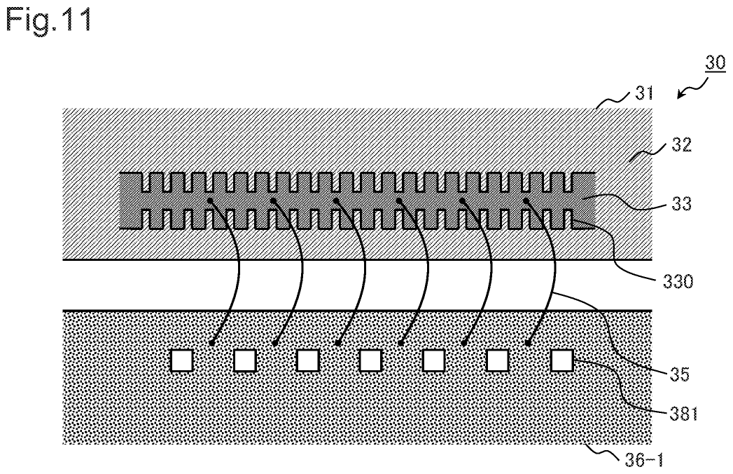

FIG. 11 is a conceptual diagram illustrating an example of a sample holder-side substrate 36-1 according to a modification of the present example embodiment. A pattern 381 is formed on the surface of the sample holder-side substrate 36-1 of the present modification. The pattern 381 is a pattern including a plurality of electrodes formed along the inner side of the sample holder-side substrate 36-1. The plurality of electrodes is formed on the surface of the substrate of the sample holder-side substrate 36-1. The pattern 381 may be a pattern formed of an insulating material instead of a pattern formed of a conductive electrode.

The plurality of electrodes constituting the pattern 381 is formed in accordance with the periodicity of the periodic structure 330 of the quantum chip 30. The size of the electrode constituting the pattern 381 may be different from the size of the adjacent electrode. For example, the pattern 381 may have a shape in which large electrodes and small electrodes are periodically arranged. The shape of the electrode may be a circle or a triangle instead of a rectangle. The pattern 381 may have a shape having periodicity such as a sine wave extending along the longitudinal direction of the electrode 33 of the quantum chip 30.

As described above, the quantum device of the present example embodiment includes the quantum chip and the sample holder. The quantum chip includes a substrate, a superconducting layer, an electrode, and a periodic structure. The substrate is a high-resistance semiconductor substrate having higher electric resistance than a general semiconductor. The superconducting layer is formed on the surface of the substrate. The electrode is formed on the surface of the superconducting layer along the outer edge of the substrate. The periodic structure is formed on the surface of the superconducting layer along the outer edge of the substrate. A quantum chip is mounted on the sample holder.

The quantum device of the present example embodiment includes a quantum chip having a periodic structure formed on the surface of the superconducting layer along the outer edge of the substrate. The periodic structure serves as a marking for wire bonding performed on the electrode. According to the present example embodiment, by working with the periodicity of the periodic structure as a marking, workability of wire bonding is improved, and fluctuations in the density of the bonding wires can be reduced.

In one aspect of the present example embodiment, a pattern serving as a marking of a position of a bonding wire used for electrical connection with the quantum chip is formed on the sample holder-side substrate. According to the present aspect, by working with the periodic structure of the quantum chip and the pattern of the sample holder-side substrate as a marking, workability of wire bonding is improved, and fluctuations in the density of the bonding wires can be reduced.

### Fourth Example Embodiment

Next, a quantum computer according to a fourth example embodiment will be described with reference to the drawings. The quantum computer of the present example embodiment mounts the quantum chip of each example embodiment. Hereinafter, an example in which the quantum computer of the present example embodiment includes a plurality of devices will be described. The plurality of devices included in the quantum computer of the present example embodiment may be arranged at close positions or may be arranged at distant positions. The quantum computer of the present example embodiment may be configured as a quantum calculation system in which a plurality of devices is arranged in a distributed manner.

The quantum computer of the present example embodiment executes a massively parallel operation using principles of quantum mechanics such as superposition and quantum entanglement. For example, the quantum computer of the present example embodiment is a quantum computer of a gate type, an annealing type, or the like. The gate-type quantum computer can perform specific calculations related to prime factorization, database search, and the like at a higher speed than the Neumann-type computer. The annealing-type quantum computer can calculate a combination optimization problem at high speed and with high accuracy. The quantum computer of the present example embodiment is not limited to a gate type or an annealing type. The following configuration is an example, and does not limit the quantum computer of the present example embodiment.

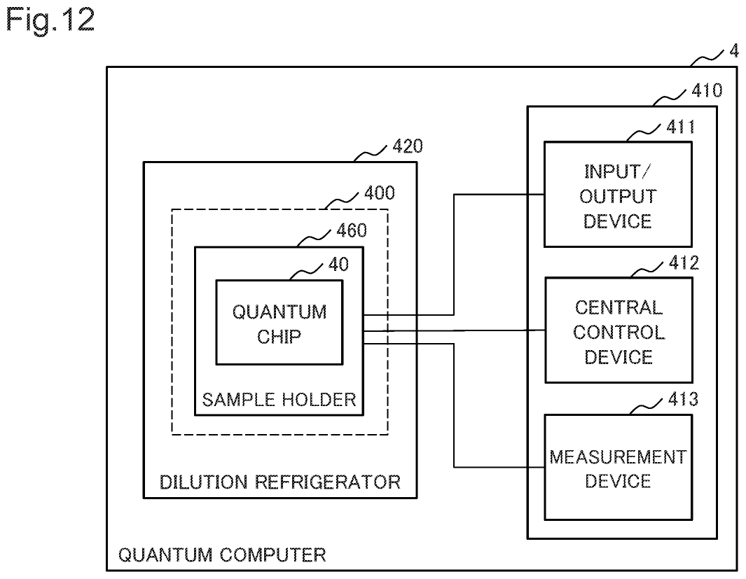

FIG. 12 is a block diagram illustrating an example of a configuration of a quantum computer 4 according to the present example embodiment. The quantum computer 4 includes a quantum device 400, a dilution refrigerator 420, an input/output device 411, a central control device 412, and a measurement device 413. The quantum device 400 is stored inside the dilution refrigerator 420. The quantum device 400 includes a quantum chip 40 and a sample holder 460. The input/output device 411, the central control device 412, and the measurement device 413 constitute a control device 410. The control device 410 may include at least one of the input/output device 411, the central control device 412, and the measurement device 413. The environmental temperature at which the control device 410 is installed is not particularly limited.

The dilution refrigerator 420 is a refrigerator that achieves a cryogenic temperature environment of equal to or less than 10 mK. For example, the dilution refrigerator 420 is achieved by a continuous refrigerator using a mixed solution of helium 3 and helium 4. The quantum device 400 is stored in the dilution refrigerator 420 (cryogenic environment). The dilution refrigerator 420 may be controlled by the control device 410 or may be controlled by a device different from the control device 410.

The quantum device 400 is stored in the dilution refrigerator 420 (cryogenic environment). The quantum device 400 disposed in a cryogenic environment and the control device 410 installed in a normal-temperature environment are connected via a transmission line (not illustrated).

The input/output device 411 is an information processing device used in quantum computation using the quantum chip 40. The input/output device 411 includes an interface that receives a user's operation, and the input/output device 411 transmits a signal input according to the user's operation to the quantum chip 40. The input/output device 411 receives a calculation result by the quantum chip 40. The input/output device 411 outputs the received processing result. For example, the input/output device 411 displays the received processing result on a display unit (not illustrated). The input/output device 411 may transfer the received processing result to another device or system.

The input/output device 411 is achieved by a general-purpose computer or a dedicated computer specialized for quantum calculation. For example, the input/output device 411 includes a central processing unit (CPU), a random access memory (RAM), a read only memory (ROM), a flash memory, and the like. For example, the input/output device 411 is achieved by a stationary computer. The input/output device 411 may be achieved by a portable terminal device such as a tablet or a smartphone.

The central control device 412 is an information processing device that controls the operation of the quantum computer 4. For example, the central control device 412 performs switching control between calibration and calculation, selection control of a quantum bit to be measured, and switching control of a measurement mode in the measurement device 413. The central control device 412 outputs a control signal at the timing of calibration or calculation. For example, the central control device 412 outputs a control signal to a switching device (not illustrated) connected to the input/output device 411 and the measurement device 413. At the timing of a measurement operation such as calibration, the central control device 412 connects the measurement device 413 to the quantum chip 40. At the timing of an arithmetic operation such as a quantum computation, the central control device 412 connects the input/output device 411 to the quantum chip 40.

The central control device 412 controls the input/output device 411 and the measurement device 413 to perform either measurement or calculation. At the time of measurement, the central control device 412 sets parameters and the like for measurement in the measurement device 413, and sets a quantum bit to be sampled and a measurement mode. For example, the central control device 412 acquires a reflection measurement result of the quantum bits included in the quantum chip 40 from the measurement device 413, and derives calibration data in accordance with theoretical calculation or the like. For example, at the time of calculation, the central control device 412 may set measurement parameters such as a signal frequency to the signal generator or the like of the input/output device 411 in accordance with calibration data.

The central control device 412 is achieved by a general-purpose computer or a dedicated computer specialized for quantum calculation. For example, the central control device 412 includes a CPU, a RAM, a ROM, a flash memory, and the like. The central control device 412 may be achieved by a microcomputer or a microcontroller. For example, the central control device 412 is constructed in a server or a cloud. The central control device 412 may be achieved by a terminal-type computer.

The measurement device 413 performs measurement according to the control of the central control device 412. For example, the measurement device 413 includes at least one of devices such as a microwave signal generator, a direct current source, a spectrum analyzer, a network analyzer, and a signal generator. In the measurement device 413, parameters and the like for measurement are set according to the control of the central control device 412. For example, setting of a quantum bit to be sampled and a measurement mode are set in the measurement device 413. For example, the measurement device 413 performs reflection measurement of a quantum bit included in the quantum chip 40. The measurement device 413 outputs a measurement result to the central control device 412.

As described above, the quantum computer of the present example embodiment includes the quantum device, the dilution refrigerator, and the control device. The quantum device has a quantum chip and a sample holder. The quantum chip includes a substrate, a superconducting layer, an electrode, and a periodic structure. The substrate is a high-resistance semiconductor substrate having higher electric resistance than a general semiconductor. The superconducting layer is formed on the surface of the substrate. The electrode is formed on the surface of the superconducting layer along the outer edge of the substrate. The periodic structure is formed on the surface of the superconducting layer along the outer edge of the substrate. The quantum chip is mounted on the quantum device. The quantum device is stored in the dilution refrigerator. The control device is connected to a quantum device.

A quantum computer of the present example embodiment includes a quantum device including a quantum chip having a periodic structure formed on a surface of a superconducting layer along an outer edge of a substrate. The periodic structure serves as a marking for wire bonding performed on the electrode. According to the present example embodiment, it is possible to provide a quantum computer including a quantum device which is wire-bonded using periodicity of a periodic structure as a marking and in which fluctuation of density of bonding wires is reduced.

### Fifth Example Embodiment

Next, a quantum chip according to a fifth example embodiment will be described with reference to the drawings. The quantum chip of the present example embodiment has a configuration in which the quantum chips according to the first and second example embodiments are simplified.

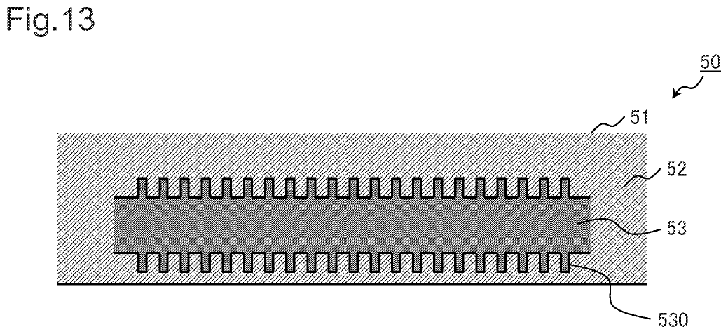

FIG. 13 is a conceptual diagram illustrating an example of a configuration of a quantum chip 50 according to the present example embodiment. The quantum chip 50 includes a substrate 51, a superconducting layer 52, an electrode 53, and a periodic structure 530. The substrate 51 is a high-resistance semiconductor substrate having higher electric resistance than a general semiconductor. The superconducting layer 52 is formed on the surface of the substrate 51. The electrode 53 is formed on the surface of the superconducting layer 52 along the outer edge of the substrate 51. The periodic structure 530 is formed on the surface of the superconducting layer 52 along the outer edge of the substrate 51.

The quantum chip of the present example embodiment has a periodic structure formed on the surface of the superconducting layer along the outer edge of the substrate. The periodic structure serves as a marking for wire bonding performed on the electrode. According to the present example embodiment, by working with the periodicity of the periodic structure as a marking, workability of wire bonding is improved, and fluctuations in the density of the bonding wires can be reduced.

The previous description of embodiments is provided to enable a person skilled in the art to make and use the present invention. Moreover, various modifications to these example embodiments will be readily apparent to those skilled in the art, and the generic principles and specific examples defined herein may be applied to other embodiments without the use of inventive faculty. Therefore, the present invention is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

1. A quantum chip comprising:
a substrate;
a superconducting layer formed on a surface of the substrate;
an electrode formed on a surface of the superconducting layer along an outer edge of the substrate; and
a periodic structure formed on a surface of the superconducting layer along an outer edge of the substrate.

2. The quantum chip according to claim 1, wherein
the periodic structure is formed as a marking of a plurality of bonding wires connected to the electrode.

3. The quantum chip according to claim 2, wherein
the periodic structure has periodicity of a fraction over an integer with respect to an interval between the plurality of bonding wires connected to the electrode.

4. The quantum chip according to claim 2, wherein
the periodic structure has a shape having periodicity in a direction perpendicular to the outer edge of the substrate.

5. The quantum chip according to claim 1, wherein
the periodic structure includes a plurality of protrusions formed on the electrode as a marking of a plurality of bonding wires connected to the electrode, and
the plurality of protrusions protrudes in a direction perpendicular to the outer edge of the substrate.

6. The quantum chip according to claim 1, wherein
the periodic structure includes a plurality of recesses formed in the electrode as a marking of a plurality of bonding wires connected to the electrode, and
the plurality of recesses is recessed in a direction perpendicular to an outer edge of the substrate.

7. The quantum chip according to claim 1, wherein
the periodic structure includes a plurality of marks formed on the superconducting layer as a marking of a plurality of bonding wires connected to the electrode.

8. A quantum device comprising:
the quantum chip according to claim 1; and
a sample holder on which the quantum chip is mounted.

9. The quantum device according to claim 8, wherein
a pattern serving as a marking of a position of a bonding wire used for electrical connection with the quantum chip is formed on a substrate on a side of the sample holder.

10. A quantum computer comprising:
the quantum device according to claim 8;
a dilution refrigerator in which the quantum device is stored; and
a controller connected to the quantum device.
